(19) United States
(12) Patent Application Publication
(10) Pub. No.: US 2025/0052834 A1
(43) Pub. Date: Feb. 13, 2025

(54) SMART CURRENT TRANSFORMER SYSTEM

(71) Applicant: Accuenergy (Canada) Inc., Toronto (CA)

(72) Inventors: Yufan Wang, Toronto (CA); Ketao Li, Toronto (CA); Liang Wang, Toronto (CA)

(73) Assignee: Accuenergy (Canada) Inc., Toronto (CA)

(21) Appl. No.: 18/231,792

(22) Filed: Aug. 9, 2023

(51) Int. Cl. G01R 31/58; G01R 15/14; G01R 15/18; G01R 22/06; G01R 35/00; G01R 35/02

(52) U.S. Cl. CPC G01R 31/58; G01R 15/148; G01R 15/185; G01R 22/063; G01R 35/005; G01R 35/02

(57) ABSTRACT

The present invention pertains to a device designed for accurate current measurement in a primary conductor. Key components include a current transformer, equipped with a secondary winding and a specified turns ratio, capable of converting the primary current into a proportionally scaled-down secondary current. Integral to the device's operation is a machine-readable code affixed to the current transformer. This code, encoded with calibration data specific to the current transformer's performance characteristics, ensures precise measurements and enhances the device's overall reliability and functionality.

### FIELD OF THE INVENTION

The present invention relates to the field of electrical current and energy measurement and management systems. More particularly, the present invention relates to a smart current transformer system.

### BACKGROUND OF THE INVENTION

A current transformer (CT) is a type of transformer that is used to measure alternating current (AC). It produces a current in its secondary which is proportional to the current in its primary. Current transformers are commonly used in metering and protective relays in the electrical power industry. They are instrumental in the safe handling of high voltage measurements, converting the high voltage or current down to a lower level for devices to measure.

A current transformer typically consists of numerous turns of wire encircling the cross-section of a toroidal core. The cable carrying the load current runs through the opening at the center of the toroidal core, forming the primary winding of the transformer. The wire encircling the core's cross-section make up the secondary winding. The primary current flowing in the primary winding generates a corresponding secondary voltage and current in the secondary winding. This secondary current is directly proportional to the primary current. The secondary winding is commonly linked to a set of resistors, and the primary current's magnitude is calculated based on the output voltage from this resistor network. Since the primary winding is a single loop, the secondary current (I₂) ideally equals the load current (I₁) in the primary winding divided by the number of loops in the secondary winding, expressed as:

$${I}_{1} = {I}_{2} ( n ) \qquad ( 1 )$$

where n=number of turns in the secondary winding.

However, real-world transformers are not perfect, and the core's magnetization introduces errors that affect the meter's accuracy. A portion of the primary winding's current is used to magnetize the transformer core, resulting in a smaller secondary current than expected from the multiplication of the primary current and the turns ratio. As illustrated in FIG. 1, the ratio error (rₑ) changes with the magnitude of the primary current (I₁) as follows:

$${r}_{e} ( \% ) = {K}_{3} + {K}_{4} ( log {I}_{1} ) \qquad ( 2 )$$

where K₃ and K₄ are constants.

The ratio error modifies the relationship between the measured secondary current (12) and the primary current (I₁), causing it to deviate from the theoretical relationship to:

$$\begin{matrix}{I}_{1} = {{I}_{2}}^{′} & ( n + n {r}_{e} / 100 )\end{matrix} \qquad ( 3 )$$

where I₂′=measured secondary current.

Moreover, the measured secondary current's magnitude (12′) relates to the theoretical secondary current (I₂) as follows:

$$\begin{matrix}{I}_{2} = {{I}_{2}}^{′} & ( 1 + {r}_{e} / 100 )\end{matrix} \qquad ( 4 )$$

Furthermore, the magnetization of the transformer core and windings results in a phase shift between the primary and secondary winding currents. Due to the inductive nature of the transformer core, the secondary current's phase lags the primary current's phase. As depicted in FIG. 2, the phase error (pₑ) changes with the primary current's magnitude (I₁) as per the equation:

$${p}_{e} = {K}_{1} + {K}_{2} ( {{I}_{1}}^{- M} ) \qquad ( 5 )$$

where M, K1, and K2 are constants.

In practical scenarios, M often approximates ½, allowing for the use of a square root approximation in the overall correction algorithm. The constants K₁, K₂, K₃, and K₄ are influenced by the specific current transformer's configuration, including factors like core material and turns ratio, and are typically determined through experimental testing on samples of a given core configuration. Normally, K₁, K₂, K₃, and K₄ are ascertained for a specific transformer configuration or production batch by comparing the actual performance of a transformer sample against the performance of a standard device when the secondary winding is connected parallel to a specific impedance or burden.

Typically, the error correction factors are generated from a sample of a particular transformer configuration and stored in the memory of the meter's data processing system, often as a table or a mathematical formula relating the error factors to the magnitude of the sensed current. When the current is sampled, the data processing system looks up or calculates the appropriate error correction factors for a current equal to the sensed current and adjusts the magnitude of the sensed current as required by the ratio and phase error correction factors.

Since the phase and ratio errors are peculiar to a particular current transformer or batch of current transformers, maintaining the desired accuracy of the power meter when replacing or adding a current transformer often necessitates reprogramming the meter to update the phase and ratio error correction factors for the new transformer.

What is desired, therefore, is a current transformer whose phase and ratio error correction factors can be programmed in a power meter easily and accurately.

### SUMMARY OF THE INVENTION

This invention relates to the field of electrical current measurement and, more particularly, to a system, device, and method for accurately determining the primary current in a conductor using a calibrated current transformer. The system comprises a current transformer equipped with a secondary winding and a specific turns ratio. The transformer encircles the primary conductor, converting the primary current into a scaled-down secondary current, proportional to the turns ratio.

Key to the invention is a machine-readable code, securely affixed to the transformer's surface, which encodes calibration data specific to the transformer's performance characteristics. This calibration data ensures precise measurement of the primary current, reducing errors typically associated with transformer-based current measurements.

The invention also extends to a power meter installation system, where the power meter interfaces with the transformer's secondary winding to measure the secondary current. This power meter can accept calibration data from a portable scanning device that scans the machine-readable code on the transformer, enabling the calibration of the measured secondary current to accurately determine the primary current.

Moreover, the invention outlines a method for determining primary current. This involves installing the calibrated current transformer on the primary conductor, establishing a connection between the transformer and a power meter, measuring the secondary current using the power meter, receiving calibration data from the scanned code, and then using this data to calibrate the secondary current measurement for accurate primary current determination.

In essence, this invention provides a comprehensive solution for enhancing the accuracy of primary current measurements using a calibrated current transformer, contributing significantly to improved power management and energy efficiency.

### BRIEF DESCRIPTION OF THE DRAWINGS

FIG. 1 is a graph of ratio error versus primary current for an exemplary current transformer.

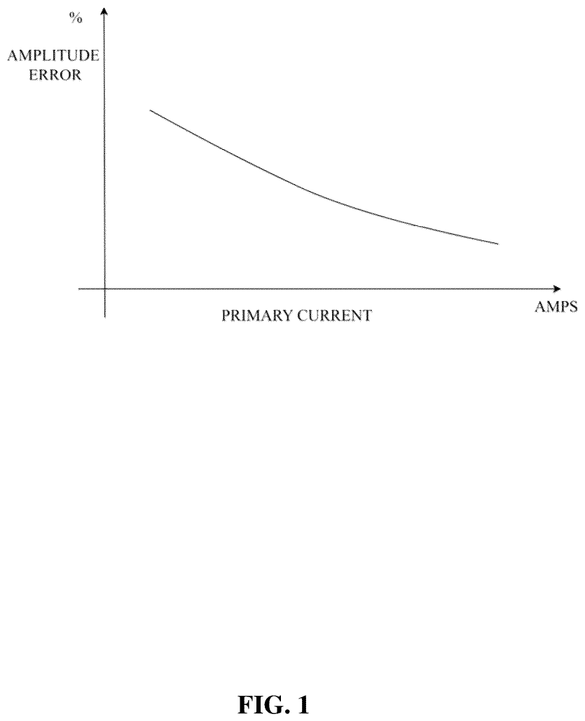

FIG. 2 is a graph of phase error versus primary current for an exemplary current transformer.

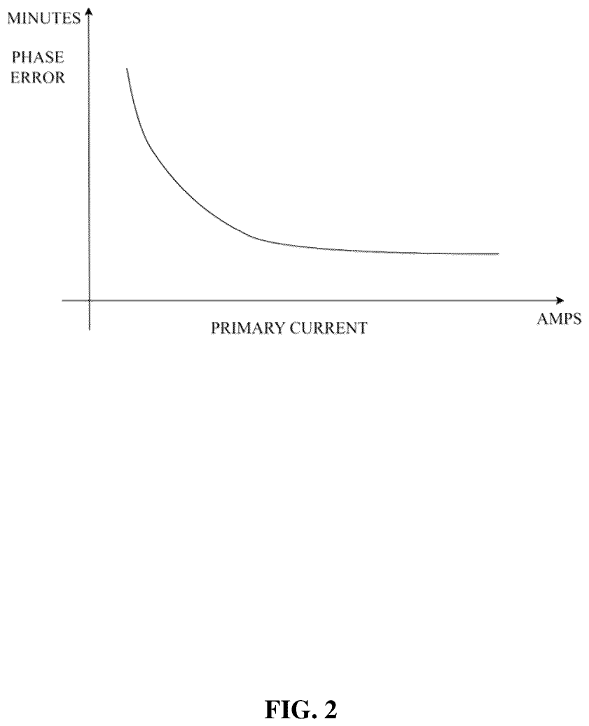

FIG. 3 is a schematic diagram of a current transformer and power meter installation system according to some embodiments of the invention.

FIG. 4 is a schematic diagram showing the process of data encryption and digital signature creation according to some embodiments of the invention.

FIG. 5 is a table outlining essential data in accordance with some embodiments of the invention.

### DETAIL DESCRIPTIONS OF THE INVENTION

Embodiments of the present disclosure will be described herein with reference to the accompanying drawings. In the following descriptions, well-known functions or constructions are not described in detail to avoid obscuring the present disclosure. The word “exemplary” is used herein to mean “serving as an example.” Any configuration or design described herein as “exemplary” is not to be construed as preferred, or advantageous, over other configurations or designs. Herein the phrase “coupled” is defined as “directly connected to or indirectly connected with” one or more intermediate components. Such intermediate components may include both hardware and software-based components.

It is further noted that, unless otherwise indicated, all functions described herein may be implemented in either software, hardware, or some combination thereof.

It should be recognized that the present disclosure can be performed in numerous ways, including as a process, an apparatus, a system, a method, or a computer-readable medium such as a computer storage medium.

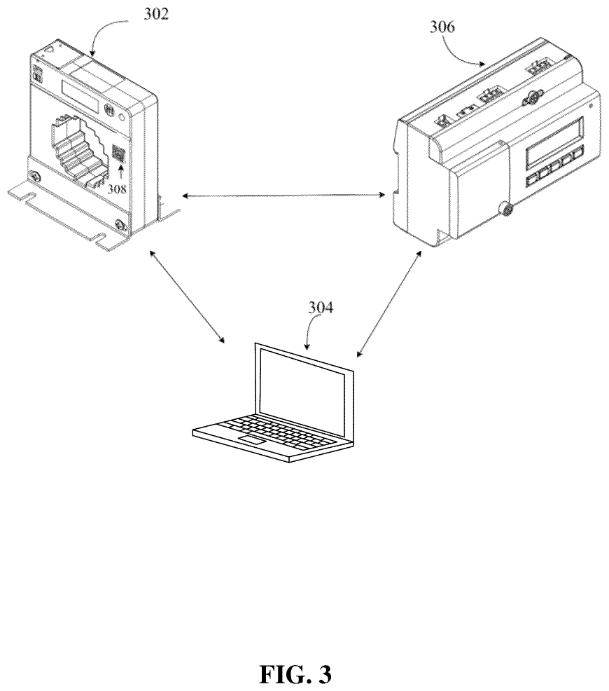

FIG. 3 illustrates a schematic diagram of a current transformer and power meter installation system. In FIG. 3, a machine-readable code 308 is placed on a surface of a current transformer 302 in a form of printing, laser, or other manner.

A machine-readable code is a type of data representation that can be automatically read and processed by machines, such as computers or specialized scanning devices. These codes are designed to encapsulate data in a format that's easily interpretable by these devices.

Examples of machine-readable codes include barcodes, Quick Response (QR) codes, and Data Matrix codes, among others. Barcodes, used widely in retail and inventory management, are read by optical scanners. QR codes and Data Matrix codes are types of two-dimensional barcodes that can hold larger amounts of data and are often scanned using smartphone cameras.

The machine-readable code 308 in the invention could be any of these types, or a similar technology. It's encoded with calibration data and other data, which would be scanned and interpreted by a compatible device to adjust the measurements of the current transformer for accuracy. This means that a machine could scan the code and use the calibration data to ensure the current transformer is reading the current correctly.

For illustrative purposes, this detailed description primarily references QR code as an exemplification, but it should be understood by those skilled in the art that the principles and methodologies discussed herein can be extended and applied to other forms of machine-readable codes as well.

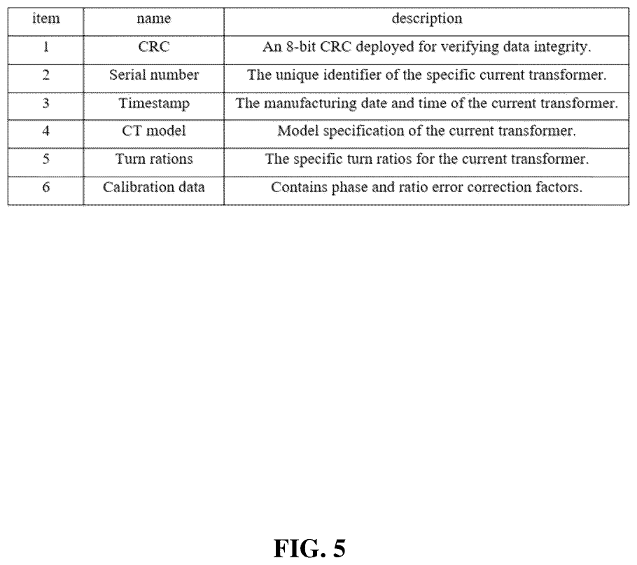

In some embodiments, the QR code 308 stores essential data pertaining to the current transformer 302. This essential data is outlined in the table shown in FIG. 5.

In some embodiments, the QR code 308 may store additional data such as operational and environmental data. Operational and Environmental Data refers to information about how a device operates under certain conditions and its resilience to environmental factors. Operational and environmental data includes operational data, optimal usage conditions and environmental resistance data. Operational and environmental data allows technicians or users to better understand how and where to best use and install the CT for optimal performance and longevity.

Operational data includes data such as the operating temperature range of the CT. For example, the QR code could contain information that the CT is designed to operate effectively between −40° C. to +85° C. If the CT operates outside of this range, its performance could be impacted, possibly leading to inaccurate readings.

Optimal usage conditions refer to the ideal conditions under which the CT performs best. For instance, the QR code could include information that the CT is most accurate when used in an environment with a stable temperature around 25° C., with minimal vibrations, and under a certain load range.

Environmental resistance data includes information on how the CT stands up to different environmental factors such as dust, water, and humidity. For example, the QR code could specify that the CT has an IP67 rating, meaning it's dust-tight and can withstand being submerged in up to 1 meter of water for up to 30 minutes.

A laptop, referenced as 304, or any other portable scanning device equipped with scanning capabilities, such as a smartphone or tablet, may be employed to scan the QR code 308 affixed to the CT 302. These devices typically contain a scanning component, such as a camera.

During the CT 302 installation, a technician initiates an application on the laptop 304. Under the application's guidance, the technician positions the laptop 304 or other scanning device appropriately to scan QR code 308. Upon successful scanning of QR code 308, the application interprets the scanned image and extracts the information embedded within the QR code 308.

The application validates the integrity of the QR code's contained information through the use of the embedded CRC value. Upon successful validation, this information is then conveyed to the power meter 306. The information may include essential data in the table shown in FIG. 5.

Upon receipt of the information encoded in QR code 308, the power meter 306 securely stores the calibration data, along with all other information encapsulated within the QR code 308. This data repository serves multiple important functions.

The calibration data is utilized by the power meter in the analysis and conversion of secondary current measurements to accurately determine the primary current flowing through the primary conductor. This data is crucial for ensuring precise and reliable readings.

The serial number contained within the QR code provides a unique identifier for the current transformer, enabling the power meter to track and record its service history. This log of operational performance can be invaluable for identifying patterns or potential issues. The power meter can also transmit this serial number to a server, where it is used to inform predictive maintenance strategies, helping to pre-emptively address any potential problems and optimize transformer lifespan.

In addition, the server utilizes the serial number for inventory management purposes. The server can track the location and status of each current transformer, contributing to efficient resource allocation and minimizing downtime.

The timestamp encoded in the QR code allows for the tracking of the current transformer's age. This information assists in the scheduling of regular inspections, replacements, or recalibrations, ensuring optimal operational efficiency and reliability throughout the transformer's lifespan.

The specific model of the transformer is also recorded in the QR code. This information allows the power meter or other associated devices to automatically identify, download, and install software updates specific to that CT model, ensuring optimal performance and compatibility. This automation saves time, improves accuracy, and reduces the likelihood of software-related issues.

The QR code also encodes the transformer's turn ratios, which are crucial for the accurate calculation of primary current. The power meter uses this data to correctly scale the measured secondary current.

Finally, the power meter can transmit all the collected and processed data to the server for further management, facilitating a holistic and dynamic approach to transformer operation and maintenance. This comprehensive data management process contributes to the extended longevity and reliability of the current transformer, enabling consistent and precise current measurements.

In some embodiments, the power meter 306 is interconnected with the secondary winding of the current transformer 302 through a connection cable.

In some embodiments, the application could evaluate the operational and environmental data extracted from the QR code 308 and compare it with the actual working conditions of the CT. Based on this comparison, the application could advise the technician regarding the suitability of the installed CT for the given conditions.

In other embodiments, after scanning, the application could include an automatic QR code verification system to verify the integrity and validity of the QR code itself, not just the information it contains. This can provide a double-layered check, ensuring the QR code is neither damaged nor counterfeit before proceeding with the data extraction. The automatic QR code verification system would add an extra layer of security and efficiency to the process of scanning QR codes. Here's how it could work in more detail: When the technician uses the application to scan the QR code on the current transformer, the application will capture an image of the QR code. Before interpreting the data stored in the QR code, the application will first check the validity of the QR code itself. This can involve checking for damages (like smudges or scratches that could affect the code's readability), assessing the clarity of the image (to ensure it's not too blurry or poorly lit), and confirming that the QR code follows the correct formatting and sizing standards. Many QR codes are designed with error correction features that allow the code to still be read even if part of it is damaged. The automatic verification system could utilize these features to correct any errors it detects in the QR code. Once the QR code has been validated and any necessary corrections have been made, the application can then proceed to interpret the data stored in the QR code and perform the CRC check to verify the data's integrity.

This system of automatic QR code verification could make the process of scanning QR codes more secure and efficient, reducing the risk of data corruption or loss. It could also make the technician's job easier, as the application would provide instant feedback on the QR code's validity and readability.

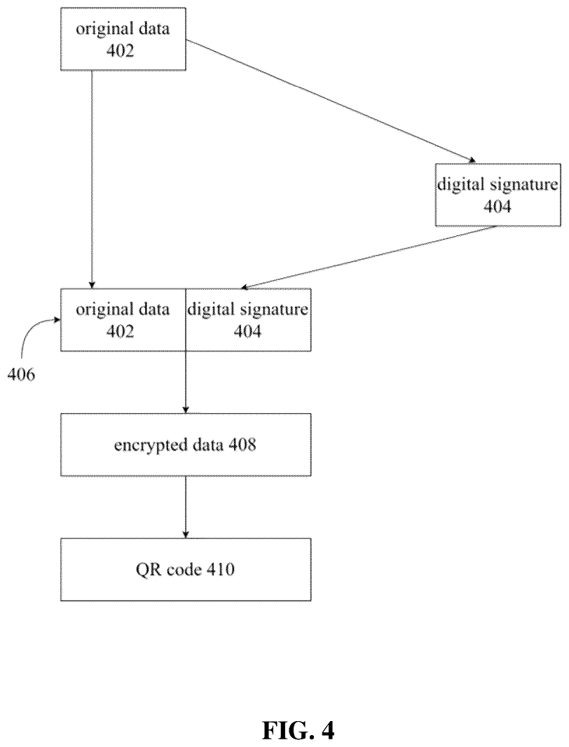

In some embodiments, the information stored in the QR code 308 is safeguarded through encryption. FIG. 4 illustrates the process of data encryption and digital signature creation.

As depicted in FIG. 4, the QR code generator retrieves the original data 402 pertaining to CT 302. This original data 402 may encompass the essential data as displayed in the table shown in FIG. 5, in addition to supplementary information, such as operational and environmental data. The QR code generator uses a hash function and a private key K₁ to generate a digital signature 404 from the original data 402. Following this, the digital signature 404 and original data 402 are compiled to form a data block 406. The data block 406 is then encrypted using a public key K₂, resulting in the creation of encrypted data 408. Subsequently, a QR generator fabricates a QR code 410 derived from the encrypted data 408. This QR code 410 is then affixed to CT 320, superseding the previous code 308. Note that the public key K₁ and the private key K₂ are complementary keys from the same key pair.

During the installation of CT 302 with the QR code 410, a technician activates an application on laptop 304. Guided by the application, the technician aligns the laptop or other scanning device to scan QR code 410. Following this, the application can utilize an automatic QR code verification system to assess the integrity and authenticity of the QR code.

Afterwards, the application decodes the scanned image and retrieves the encrypted data 408 concealed within the code 410. This encrypted data 408 is then transmitted to power meter 306, which decrypts the encrypted data using private key K₂ to extract the data block 406. This block includes the original data 402 and digital signature 404.

The power meter generates a calculated digital signature by hashing the original data 402 found in the data block 406, using private key K₂. It then compares this calculated digital signature with the digital signature 404. A match between the calculated and original digital signatures signifies the data's integrity, prompting the power meter 306 to parse the original data to obtain the basic and supplemental information.

The essential information assists in the processing of current data, while the supplemental information is relayed to laptop 304. The application on the laptop then scrutinizes the operational and environmental data drawn from the supplemental information, comparing it with the real-time working conditions of the CT. Based on this analysis, the application can provide insights to the technician about the aptness of the installed CT for the given conditions.

If a discrepancy is observed between the calculated digital signature and the digital signature 404, the power meter 306 conveys this incongruity to the application for further examination and action. This multi-level verification process ensures data security, enhancing the reliability and precision of the current transformer installation.

In relation to FIG. 3, it is pertinent to mention that multiple embodiments and alternatives can be realized. While the embodiments above describe and depict a machine-readable code 308 and a laptop 304, it's important to note that different configurations are plausible. For instance, the machine-readable code 308 might be substituted or complemented by a Radio Frequency Identification (RFID) tag or a Near Field Communication (NFC) tag. These tags, providing alternate or supplementary data storage and transmission avenues, come with unique benefits such as contactless data interchange or enhanced durability under severe environmental conditions. Similarly, the laptop 304, employed for reading the machine-readable code 308, can be substituted, or complemented by a dedicated device outfitted with an RFID reader or an NFC reader, thereby simplifying the reading and interpretation of data from the RFID or NFC tags. These dedicated devices can be standalone units or can be incorporated into other systems or devices for a seamless data reading process. This invention encompasses all such suitable alternatives or supplementary features, or any amalgamation thereof, aimed at achieving similar objectives.

RFID or Radio Frequency Identification employs radio waves for automatic identification and tracking of tags attached to objects. The tags contain electronically stored information and can be powered in several ways ranging from passive tags that harness energy from the radio waves of a nearby RFID reader, to active tags that possess a local power source and can operate hundreds of meters away from the RFID reader. RFID finds usage in myriad applications including product tracking, access control, and contactless payment systems. A key advantage of RFID is that it doesn't require a direct line of sight to read data from a tag, implying that tags can be read while enclosed in a box, embedded within objects, or otherwise obscured.

NFC or Near Field Communication is a communication protocol enabling two electronic devices to communicate when they are within 4 cm (1.6 inches) of each other. Typically, one device is a smartphone or another NFC-enabled device, while the other is usually a tag embedded in a poster, sticker, or another object. NFC tags, which can be read by an NFC-enabled device, can store data like URLs, text data, or commands to modify device settings. They are usually deployed in applications such as contactless payment systems, advertising, and information sharing.

The principal difference between NFC and RFID lies in the range at which they operate. NFC is designed for very short-range communication, typically a few centimeters, while RFID can function over substantially longer distances.

In certain embodiments, the current transformer 302 could be outfitted with an RFID tag that holds its calibration data. A specialized device, equipped with an RFID reader, could then wirelessly read this data. Upon installation of a new current transformer, the operator prompts the RFID reader on the device to read the tag and retrieve the calibration data. This data is subsequently transmitted to the power meter, either wirelessly or via a wired connection, and is employed to calibrate the power meter's measurements.

In other embodiments, the current transformer 302 could be fitted with an NFC tag that stores the calibration data. A specialized device with an NFC reader, due to NFC's close proximity requirement, can read the data when the device is brought near the current transformer. On detecting the NFC tag, the device retrieves the calibration data, which is subsequently transmitted to the power meter for the calibration of its measurements.

In the above-described embodiments, the specialized device could be a handheld device or a mobile device equipped with the necessary RFID or NFC reading capabilities. The calibration data can be transmitted to the power meter via a wired or wireless connection, encompassing Wi-Fi, Bluetooth, or any proprietary connection. These embodiments provide a flexible and efficient methodology for obtaining calibration data and ensuring the power meter is accurately calibrated to each specific current transformer.

In other embodiments, the current transformer 302 could be equipped with an RFID tag storing its calibration data. The power meter 306, equipped with an RFID reader, can then wirelessly read this data. When a new current transformer is installed and connected to the power meter, the power meter prompts its RFID reader to read the tag and retrieve the calibration data. This data is then utilized to calibrate the power meter's measurements.

The detailed description above sets forth numerous specific details to provide a thorough understanding of the present invention. However, those skilled in the art will appreciate that the present invention may be practiced without these specific details. In other instances, well known methods, procedures, components, and circuitry have not been described in detail to avoid obscuring the present invention.

The terms and expressions that have been employed in the foregoing specification are used as terms of description and not of limitation, and there is no intention, in the use of such terms and expressions, of excluding equivalents of the features shown and described or portions thereof, it being recognized that the scope of the invention is defined and limited only by the claims that follow.

The following is claimed:

1. A device for measuring current in a primary conductor, the device comprising:
a current transformer equipped with a secondary winding and having a specified turns ratio, which is designed to encircle the primary conductor and convert the primary current flowing through the primary conductor into a proportionally scaled-down secondary current in accordance with the turns ratio; and
a machine-readable code securely affixed to a surface of the current transformer, wherein the machine-readable code is encoded with calibration data pertinent to the current transformer's performance characteristics.

2. The device of claim 1, wherein the current transformer is configured to be linked with a power meter, facilitating the measurement of the secondary current flowing through the secondary winding.

3. The device of claim 1, wherein the machine-readable code also encodes supplementary data related to the current transformer, the supplementary data comprising at least one of:
the turns ratio;
the date and time of manufacture;
a distinct serial number;
and the model designation of the current transformer.

4. The device of claim 1, wherein the machine-readable code is further encoded with operational and environmental data pertaining to the current transformer, the operational and environmental data comprising at least one of:
operational data that specifies the operating temperature range of the current transformer;
optimal usage conditions indicating the ideal conditions under which the current transformer performs optimally; and
environmental resistance data providing information on the current transformer's resilience to environmental factors such as dust, water, and humidity.

5. A current transformer and power meter installation system comprising:
a current transformer equipped with a secondary winding and having a specified turns ratio, which is designed to encircle the primary conductor and convert the primary current flowing through the primary conductor into a proportionally scaled-down secondary current in accordance with the turns ratio; and
a machine-readable code securely affixed to a surface of the current transformer, wherein the machine-readable code is encoded with calibration data pertinent to the current transformer's performance characteristics;
a power meter interfaced with the secondary winding, purposed to measure the secondary current on the secondary winding, wherein the power meter is designed to accept calibration data from a portable scanning device, thereby enabling the calibration of the measured secondary current for accurate determination of the primary current; and
a portable scanning device, provisioned with capabilities to scan the machine-readable code, thereby retrieving calibration data related to the current transformer and conveying this data to the power meter for calibration purposes.

6. The system of claim 5, wherein the machine-readable code is further encoded with additional information pertaining to the current transformer, the additional information selected from the group comprising:
the turns ratio;
the manufacturing timestamp;
a unique serial number;
and the specific model of the current transformer.

7. The system of claim 5, wherein the machine-readable code is further encoded with operational and environmental data pertaining to the current transformer, the operational and environmental data comprising:
operational data that specifies the operating temperature range of the current transformer;
optimal usage conditions indicating the ideal conditions under which the current transformer performs optimally; and
environmental resistance data providing information on the current transformer's resilience to environmental factors such as dust, water, and humidity.

8. A method for determining a primary current through a primary conductor, the method comprising:
installing on the primary conductor, a device comprising:
a current transformer equipped with a secondary winding and having a specified turns ratio, which is designed to encircle the primary conductor and convert the primary current flowing through the primary conductor into a proportionally scaled-down secondary current in accordance with the turns ratio; and
a machine-readable code securely affixed to a surface of the current transformer, wherein the machine-readable code is encoded with calibration data pertinent to the current transformer's performance characteristics;
establishing a connection between a power meter and the current transformer via the secondary winding;
measuring a secondary current at the secondary winding utilizing the power meter, and at the power meter:
receiving the calibration data from a portable scanning device which is provisioned to scan the code, thereby retrieving calibration data related to the current transformer; and
using the received calibration data to calibrate the measured secondary current to accurately determine the primary current.

9. The method of claim 8, wherein the machine-readable code is further encoded with additional information pertaining to the current transformer, the additional information selected from the group comprising:
the turns ratio;
the manufacturing timestamp;
a unique serial number;
and the specific model of the current transformer.

10. The method of claim 9, wherein the machine-readable code is further encoded with operational and environmental data pertaining to the current transformer, the operational and environmental data comprising:
operational data that specifies the operating temperature range of the current transformer;
optimal usage conditions indicating the ideal conditions under which the current transformer performs optimally; and
environmental resistance data providing information on the current transformer's resilience to environmental factors such as dust, water, and humidity.

11. The method of claim 10, further comprising the step of storing, by the power meter, at least one of the additional information, and operational and environmental data encoded in the machine-readable code.

12. The method of claim 11, further comprising the steps of the power meter utilizing the serial number encoded in the machine-readable code to trace and document the service history of the current transformer and forwarding the serial number to an energy management server for enabling predictive maintenance and inventory management strategies.
